(19) United States
(12) Patent Application Publication
(10) Pub. No.: US 2007/0113108 A1
(43) Pub. Date: May 17, 2007

(54) MEMORY WITH SELF-CONTAINED POWER SUPPLY

(75) Inventor: Shih-Hsiung Lien, Shih-Lin District, Taipei City (TW)

Correspondence Address: OPTIMUM CARE INTERNATIONAL TECH. INC., P.O. BOX 108-00403, TAIPEI, TW

(73) Assignee: OPTIMUM CARE INTERNATIONAL TECH. INC., Taipei City (TW)

(21) Appl. No.: 11/383,483

(22) Filed: May 15, 2006

(30) Foreign Application Priority Data
Nov. 11, 2005 (TW) 094139681

(51) Int. Cl. G06F 1/00; G11C 5/14

(52) U.S. Cl. 713/300; 365/228

(57) ABSTRACT

The present invention provides a rechargeable battery module for supplying a sufficient power to recharge the DRAM in order to maintain the stored data. Thus, the problems of losing the data in the DRAM due to cut in power supply can be avoided. Therefore, the DRAM may replace the flash memory in the electronic devices. Thus the overall cost of the electronic device can be effectively reduced.

This application claims the priority benefit of Taiwan patent application number 094139681 filed on Nov. 11, 2005.

### BACKGROUND OF THE INVENTION

1. Field of Invention

The present invention generally relates to a memory with self-contained power supply, and more particularly to a memory comprising a rechargeable battery module to supply power for maintaining data stored in the memory to avoid losing the data during power outages.

2. Background of Invention

Along with the advancement of the electronic industry and the rapid development of electronic technology, increasing number of electronic devices is used in the life to provide convenience and upgrade the quality of our life. Memories are widely applied in various types of the electronic devices for storing as well as for exchanging data and as a temporary storage. Especially, computers, communication devices and consumer electronic devices are very popular at present.

A common type of memory is a random access memory (RAM). RAM is classified into two different types, namely, static random access memory (SRAM) and dynamic random access memory (DRAM). SRAM comprises a transistor for storing data. Because the transistor needs not to be refreshed, therefore SRAM has faster processing speed, however the cost is higher. Whereas, DRAM comprises a capacitor for storing data, and because the electric charge stored in the capacitor is slowly discharged, therefore the capacitor of the DRAM must be refreshed regularly in order to maintain the stored data. As the term “dynamic” indicates that the data stored in the memory will be lost when the power supply is cut during shut down of the computer or when the computer breakdown, and the capacitor requires to recharge of power often to maintain a potential difference in order to perform the storage function. Therefore, DRAM is mostly used for temporarily storing the data.

The other commonly used memory is a flash memory. Because of the advantageous features of flash memory, such as non-volatility, shock proof and high storage density, it has replaced EEPROM in many portable electronic devices. Recently, it is also being used to replace the hard disk and other conventional storage media. However, the cost of the flash memory is high and therefore the cost portable electronic devices are correspondingly high.

Therefore, it is important to continuously supply power to DRAM in order to maintain the stored data so that DRAM may be effectively applied in various types of portable electronic devices. In other words, by replacing the flash memory with DRAM, overall cost of the portable electronic devices may be accordingly reduced, and this is the future direction of relative manufactures that attempt to achieve.

### SUMMARY OF THE INVENTION

According to an aspect of the present invention, the rechargeable battery module supplies a sufficient power to recharge the DRAM to maintain data stored in the DRAM. Thus, the problems of losing the data in the DRAM due to cut of power supply can be avoided. Therefore, the DRAM may replace the flash memory in the electronic devices. Thus the overall cost of the electronic device can be effectively reduced.

According to another aspect of the present invention, the rechargeable battery module supplies power to the DRAM for storing data, and if the memory is misplaced, the data stored in the memory will be lost after a span of time and the rechargeable battery module is unable to supply a sufficient power, and therefore the data in the memory will not get by any unauthorized people.

### BRIEF DESCRIPTION OF THE DRAWING

FIG. 1 is a block diagram of a memory according to an embodiment of the present invention.

FIG. 2 is a block diagram of a memory according to an embodiment of the present invention.

FIG. 3 is a block diagram of a memory according to another embodiment of the present invention.

FIG. 4 is a block diagram of a device according to another embodiment of the present invention.

FIG. 5 is a block diagram of a device according to another embodiment of the present invention.

### DETAIL DESCRIPTION OF THE EMBODIMENTS

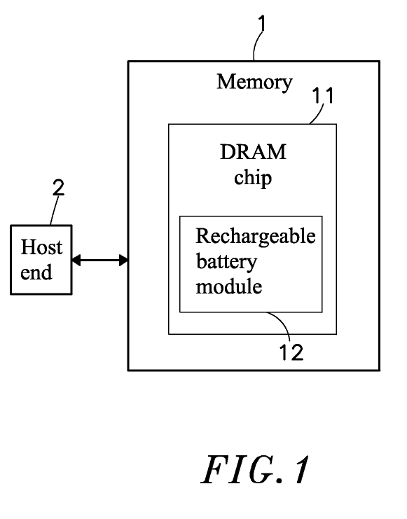

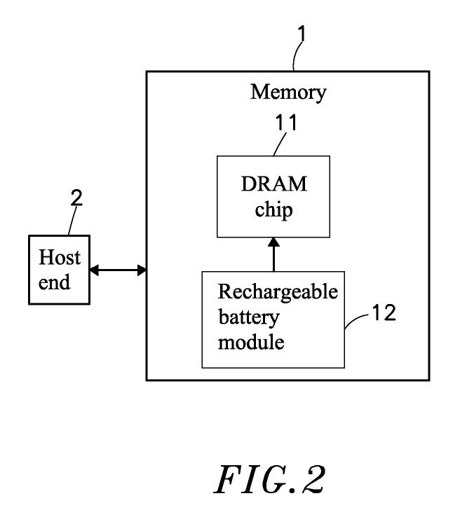

Referring to FIGS. 1 and 2, a memory 1 of the present invention comprises a DRAM chip 11 and a rechargeable battery module 12.

The DRAM chip 11 is electrically connected to the rechargeable battery module 12. The rechargeable battery module 12 is adopted for supplying power to the DRAM chip 11.

The memory 1 of the present may comprise one or more DRAM chips 11 electrically connected to the rechargeable battery module 12 via a leadframe or a suitable substrate. The DRAM chip 11 may also be integrally formed with the rechargeable battery module 12 in a single package. It should be noted that the rechargeable battery module 12, according to an embodiment of the present invention, is adopted for supplying power to the DRAM chip 11, therefore, any other equivalent device may also be used to achieve the purpose of the present invention which shall also be construed to be within the scope of the present invention.

When the memory 1 is electrically connected the host end 2, a user may perform storage/retrieval data through the host end 2. The host end 2 not only provides power to operate the DRAM chip 11 and also provides power to recharge the rechargeable battery module 12. When the memory 1 is not electrically connected to the host end 2, the rechargeable battery module 12 supplies power to the DRAM chip 11 to maintain the stored data therein. If the user misplaces the memory 1, after a span of time, the rechargeable battery module 12 will lose power and may not have sufficient power to recharge the DRAM chip 11, and the data stored in the memory 1 will be lost. Thus, the data stored in the memory 1 will not get by any unauthorized people.

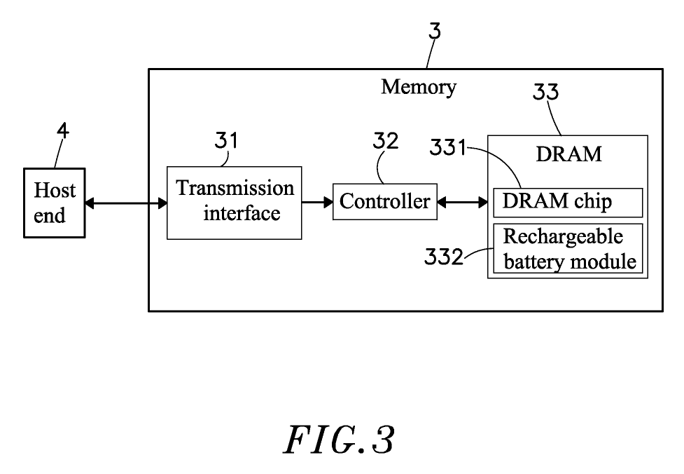

Referring to FIG. 3, a memory 3 may be applied in a portable storage device comprising a transmission interface 31, a controller 32 and a DRAM 33.

The transmission interface 31 may be electrically connected to a host end 4 and can be a USB transmission interface or SATA transmission interface.

The controller 32 may be electrically connected to the transmission interface 31 and can receive data from the host end 4 via the transmission interface 31.

The DRAM 33 may be electrically connected to the controller 32. The DRAM 33 comprises one or more of DRAM chips 331 and a rechargeable battery module 332 for supplying power to the DRAM chip 331.

When the memory 3 is electrically connected to the host end 4 via the transmission interface 31, the host end 4 can provide power to recharge the rechargeable battery module 332 of the DRAM 33 through the transmission interface 31 to maintain the rechargeable battery module 332 in saturated status. Besides, the host end 4 also can provide power to the DRAM 33 for operation, so that a user can perform storage/retrieval data through the host end 4. When the memory 3 is not electrically connected to the host end 4, the rechargeable battery module 332 supplies power to the DRAM 33 to maintain the stored data therein. So the user can use the memory 3 with lower price as a portable storage device to replace a portable disk made of flash memory. Moreover, if the user misplaces the memory 3, after a span of time, the rechargeable battery module 332 will lose power and may not have sufficient power to the DRAM 33, and the data stored in the DRAM 33 will be lost. Thus, the data in the DRAM 33 will not get by any unauthorized people.

The above-mentioned DRAM 331 is integrally formed with the rechargeable battery module 332 in a single package. The rechargeable battery module 332 is also electrically connected to the plurality of DRAM chips 331 and provides a demand power to the DRAM chips 331.

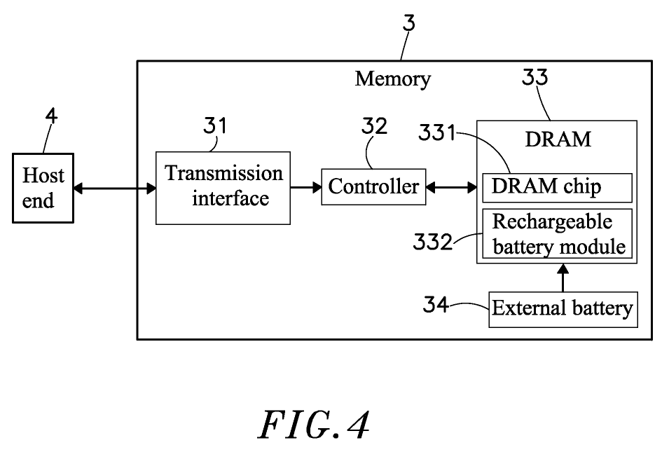

Referring to FIG. 4, the memory 3 may further comprise an external battery 34, and the external battery 34 is electrically connected to the rechargeable battery module 332 for supplying power to the memory 3 and also for recharging the rechargeable battery module 332. When the external battery 34 has insufficient power, the rechargeable battery module 332 automatically supplies power to maintain the stored data in the DRAM 33. The external battery 34 may be renew in order to recharge the rechargeable battery module 332 to constantly supply power to the DRAM 33 to form a circular supply and thereby effectively maintain the stored data.

The external battery 34 may be a dry battery, an alkaline battery or a rechargeable battery. It should be noted that the external battery 34, according to an embodiment of the present invention, is adopted for supplying power to maintain the operation of the memory 3 and recharging the rechargeable battery module 332, therefore any equivalent device may also be used to achieve the purpose of the present invention, which shall also be construed to be within the scope of the present invention.

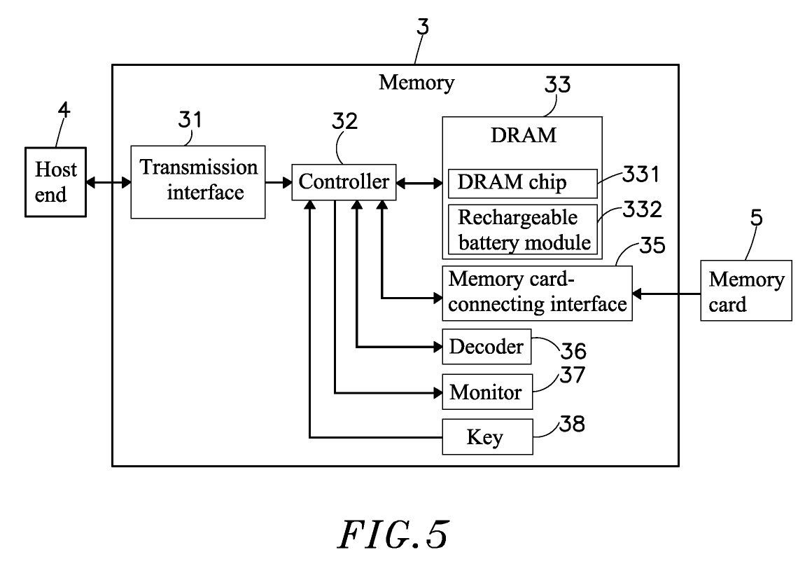

Referring to FIG. 5, the memory 3 may further comprise a memory card-connecting interface 35 electrically connected to a memory card 5 so that not only the storage capacity is promoted but also enables the user to store data in various memory cards 5.

Referring to FIG. 5 again, the memory 3 further comprises a decoder 36, a monitor 37 and keys 38. The user may store data or music files into the DRAM 33 and the decoder 36 encodes/decodes to the music files so that the user can play the music files in the DRAM 33 via a player. Furthermore, the user may view lyrics on the monitor 37 while playing the music files. The monitor 37 also can display information such as the remaining memory capacity of DRAM 33 or the memory card 5, and the amount of power of the rechargeable battery module 34. The keys 38 may be operated to play the music files, adjust the volume, turn on or off the memory 3 The above memories 1 and 3 may be applied in various types of electronic devices, such as portable disk, portable ROM, MP3 player, PDA, camera, video camera and the like. The above description is merely used to demonstrate the embodiment of the present invention, and any equivalent thereof shall also be construed to be within the scope of the present invention.

According to the above description, the present invention provides a rechargeable battery module to supply power to the DRAM for maintaining the stored data. Thus, the DRAM may be able to store the data for a long period of time.

Accordingly, the memory of the present invention has at least the following advantages.

1. The rechargeable battery module is adopted to supply power to the DRAM for maintaining the stored data, and the DRAM may replace the flash memory. Thus, it is possible to reduce the overall cost of the electronic device.

2. The external battery may be used to recharge the rechargeable battery module and when the power of the external battery is insufficient, the external battery may be refreshed. Thus, power may be continuously supplied to the DRAM.

3. If the user misplaces the memory, after a span of time, the rechargeable battery module will lose power and may not have sufficient power to the DRAM so that the data stored therein will be lost. Thus, the data stored in the memory will not get by any unauthorized people.

A prototype of memory with self-contained power supply has been constructed with the features of FIGS. 1-5. The memory with self-contained power supply functions smoothly to provide all of the features discussed earlier.

Although particular embodiments of the invention have been described in detail for purposes of illustration, various modifications and enhancements may be made without departing from the spirit and scope of the invention. Accordingly, the invention is not to be limited except as by the appended claims.

What the invention claimed is:

1. A memory with self-contained power supply, comprising:
a DRAM chip; and
a rechargeable battery module, adopted for supplying power to said DRAM chip.

2. The memory with self-contained power supply as claimed in claim 1, wherein said DRAM chip is electrically connected to said rechargeable battery module via a leadframe or a substrate.

3. The memory with self-contained power supply as claimed in claim 1, wherein said rechargeable battery module is integrally formed with said DRAM chip in a single package.

4. The memory with self-contained power supply as claimed in claim 1, wherein said memory comprises one or more DRAM chips.

5. A memory with self-contained power supply, comprising:
a transmission interface, electrically connected to a host end;
a controller, electrically connected to said transmission interface, for receiving data from said host end via said transmission interface; and
a DRAM, electrically connected to said controller, comprising at least one DRAM chip and a rechargeable battery module for supplying power to maintain data stored in said DRAM.

6. The memory with self-contained power supply as claimed in claim 5, wherein said DRAM chip is electrically connected to said rechargeable battery module via a leadframe or a substrate.

7. The memory with self-contained power supply as claimed in claim 5, wherein said rechargeable battery module is integrally formed with said DRAM chip in a single package.

8. The memory with self-contained power supply as claimed in claim 5, wherein said controller is connected to a memory card-connecting interface for electrically connecting to a memory card.

9. The memory with self-contained power supply as claimed in claim 5, wherein said controller is further connected to a decoder.

10. The memory with self-contained power supply as claimed in claim 5, wherein said controller is further connected to a monitor.

11. The memory with self-contained power supply as claimed in claim 5, wherein said controller is further connected to keys.

12. A memory with self-contained power supply, comprising:
a transmission interface, electrically connected to a host end;
a controller, electrically connected to said transmission interface, for receiving data from said host end via said transmission interface;
a DRAM, electrically connected to said controller, comprising at least one DRAM chip and a rechargeable battery module for supplying power to maintain data stored in said DRAM; and
an external battery, for supplying power to recharge said rechargeable battery module.

13. The memory with self-contained power supply as claimed in claim 12, wherein said DRAM chip is electrically connected to said rechargeable battery module via a leadframe or a substrate.

14. The memory with self-contained power supply as claimed in claim 12, wherein said rechargeable battery module is integrally formed with said DRAM chip in a single package.

15. The memory with self-contained power supply as claimed in claim 12, wherein said controller is connected to a memory card-connecting interface for electrically connecting to a memory card.

16. The memory with self-contained power supply as claimed in claim 12, wherein said controller is further connected to a decoder.

17. The memory with self-contained power supply as claimed in claim 12, wherein said controller is further connected to a monitor.

18. The memory with self-contained power supply as claimed in claim 12, wherein said controller is further connected to keys.

19. The memory with self-contained power supply as claimed in claim 12, wherein said external battery comprises a dry battery, an alkaline battery or a recharge battery.
